(19) United States
(12) Patent Application Publication
(10) Pub. No.: US 2019/0165162 A1
(43) Pub. Date: May 30, 2019

(54) SEMICONDUCTOR DEVICE AND METHOD OF MANUFACTURING A SEMICONDUCTOR DEVICE

(71) Applicant: FUJI ELECTRIC CO., LTD., Kawasaki-shi (JP)

(72) Inventors: Yusuke KOBAYASHI, Tsukuba (JP); Tsuyoshi ARAOKA, Tsukuba (JP)

(73) Assignee: FUJI ELECTRIC CO., LTD., Kawasaki-shi (JP)

(21) Appl. No.: 16/166,590

(22) Filed: Oct. 22, 2018

(30) Foreign Application Priority Data
Nov. 29, 2017 (JP) 2017-229700

(51) Int. Cl. H01L 29/78; H01L 29/16; H01L 29/08

(52) U.S. Cl. CPC H01L 29/7813; H01L 29/0878; H01L 29/086; H01L 29/1608

(57) ABSTRACT

A vertical MOSFET having a trench gate structure includes a p-type base layer and an n⁻-type drift layer formed by epitaxial growth. In the n⁻-type drift layer, an n-type region and a first p⁺-type region are provided. The n-type region is constituted by a lower n-type region and an upper n-type region that is in contact with the lower n-type region and has an impurity concentration lower than that of the lower n-type region. The lower n-type region is partially provided between trenches and between first p⁺-type regions.

### CROSS REFERENCE TO RELATED APPLICATIONS

This application is based upon and claims the benefit of priority of the prior Japanese Patent Application No. 2017-229700, filed on Nov. 29, 2017, the entire contents of which are incorporated herein by reference.

### BACKGROUND

### 1. Field

Embodiments of the invention relate to a semiconductor device and a method of manufacturing a semiconductor device.

### 2. Description of Related Art

Conventionally, to reduce the ON resistance of an element in a power semiconductor device, a vertical metal oxide semiconductor field effect transistor (MOSFET) having a trench structure is produced (manufactured). In the vertical MOSFET, the trench structure in which a channel is formed orthogonal to a substrate surface enables the cell density per unit area to be increased to a greater extent as compared to a planar structure in which the channel is formed parallel to the substrate surface. Therefore, with the trench structure, the current density per unit area may be increased, which is advantageous from the perspective of cost.

Nonetheless, when the trench structure is formed in the vertical MOSFET, the structure is such that an entire region of the inner walls of the trench are covered by a gate insulating film to form a channel in an orthogonal direction. A portion of the gate insulating film at a bottom of the trench is near a drain electrode and therefore, this portion of the gate insulating film is easily subjected to high electric field. In particular, since ultrahigh voltage elements are produced with a wide bandgap semiconductor material (semiconductor material having a wider bandgap than that of silicon such as silicon carbide (SiC)), adverse effects on the gate insulating film at the bottom of the trench significantly reduce reliability.

As a method of solving such problems, a technique has been proposed in which in a vertical MOSFET having a trench structure that has a striped flat pattern, a p⁺-type base region is provided between trenches and has a striped shape parallel to the trenches; and a p⁺-type base region is provided at each trench bottom and has a striped shape parallel to the trenches (for example, refer to Japanese Laid-Open Patent Publication No. 2015-72999). Further, a technique has been proposed in which between trenches, a p⁺-type base region having a striped shape parallel to the trenches is provided (for example, refer to Japanese Laid-Open Patent Publication No. 2015-192028).

Further, when a cell pitch is reduced to 4 μm or less, the p⁺-type base region is orthogonal to the trench, enabling a structure strongly resistant to misalignment. Hereinafter, a cross-sectional view and a sectional plan view of a conventional silicon carbide semiconductor device are depicted. FIG. 20 is a cross-sectional view of a part of a structure of the conventional silicon carbide semiconductor device at cutting line A-A′ in FIG. 25. FIG. 21 is a cross-sectional view of a part of the structure of the conventional silicon carbide semiconductor device, at cutting line B-B′ in FIG. 26. FIG. 22 is a cross-sectional view of a part of the structure of the conventional silicon carbide semiconductor device, at cutting line C-C′ in FIG. 25. FIG. 23 is a cross-sectional view of the structure of the conventional silicon carbide semiconductor device, at cutting line D-D′ in FIG. 25. FIG. 24 is a cross-sectional view of a part of the structure of the conventional silicon carbide semiconductor device, at cutting line E-E′ in FIG. 25. FIG. 25 is a sectional plan view of a part of the structure of the conventional silicon carbide semiconductor device, at cutting line G-G′ in FIG. 2. FIG. 26 is another sectional plan view of the part of the structure of the conventional silicon carbide semiconductor device, at cutting line G-G′ in FIG. 20.

The conventional silicon carbide semiconductor device depicted in FIGS. 20, 21, 22, 23, and 24 includes a MOS gate having an ordinary trench gate structure at a front surface (surface having a p-type base layer 106) side of a semiconductor base (hereinafter, silicon carbide base) that contains silicon carbide. The silicon carbide base (semiconductor chip) is formed by sequentially forming on an n⁺-type supporting substrate (hereinafter, n⁺-type silicon carbide substrate) 101 containing silicon carbide, silicon carbide layers constituting an n⁻-type drift layer 102, an n-type region 105 that is a current spreading region, and the p-type base layer 106.

As depicted in FIGS. 20 and 21, in the n-type region 105, a first p⁺-type region 103 is selectively provided that partially underlies a bottom of a trench 1018 is orthogonal to the trench 1018. The first p⁺-type region 103 is provided at a depth not reaching the n⁻-type drift layer 102. Further, as depicted in FIG. 21, in the n-type region 105 between (mesa part) adjacent trenches 1018, a second p⁺-type region 104 is selectively provided. The second p⁺-type region 104 and the first p⁺-type region 103 may be formed concurrently. The second p⁺-type region 104 is provided so as to be in contact with the p-type base layer 106. Reference numerals 107, 108, 109, 1010, 1011, 1012, 1013, and 1014 are an n⁺-type source region, a p⁺-type contact region, a gate insulating film, a gate electrode, an interlayer insulating film, a barrier metal, a source electrode, and a source electrode pad, respectively. Further, in the n-type region 105, as depicted in FIGS. 20, 21, and 22, a third p⁺-type region 1015 may be provided at the bottom of the trench 1018.

FIGS. 25 and 26 are sectional plan views of a part of the conventional silicon carbide semiconductor device at cutting line G-G′ in FIG. 20. As depicted in FIGS. 25 and 26, the second p⁺-type region 104 is provided at a surface of first p⁺-type region 103 and partially between the trenches 1018. Further, in FIGS. 20 to 22, X represents cell pitch, which is about 2.0 to 4.0 μm. In FIGS. 25 and 26, Y represents a width of the first p⁺-type region 103 along a longitudinal direction of the trench 1018 and is about 1.0 μm, Z represents an interval of the first p⁺-type region 103 along the longitudinal direction of the trench 1018 and is about 1.0 μm. In FIGS. 20 to 26, a structure in which a mesa part in which the second p⁺-type region 104 is not provided between the trenches 1018 as depicted in FIG. 25 and a mesa part in which the second p⁺-type region 104 is provided as depicted in FIG. 26 are alternately provided. However, 4 to 16 of the mesa parts in which the second p⁺-type region 104 is not provided as depicted in FIG. 25 may be provided in parallel successively and the mesa part depicted in FIG. 26 may be repeatedly formed at a ratio of one to the successive plural parallel mesa parts of FIG. 25.

In the vertical MOSFET of the configuration of FIGS. 20 to 26, pn junctions of the first p⁺-type region 103 and the second p⁺-type region 104 with the n-type region 105 are at a deeper position than is the trench 1018. Therefore, electric field concentrates at borders of the first p⁺-type region 103, the second p⁺-type region 104 and the n-type region 105, enabling a concentration of electric field at the bottom of the trench 1018 to be mitigated. Further, the second p⁺-type region 104 is orthogonal to the trench, enabling a structure strongly resistant to misalignment and a cell pitch that is 4 μm or less.

### SUMMARY

According to an embodiment, a semiconductor device includes a semiconductor substrate of a first conductivity type; a first semiconductor layer of the first conductivity type provided on a front surface of the semiconductor substrate, and having an impurity concentration that is lower than an impurity concentration of the semiconductor substrate; a first semiconductor region of the first conductivity type selectively provided in a surface layer of the first semiconductor layer on a first side of the first semiconductor layer, opposite a second side of the first semiconductor layer facing toward the semiconductor substrate, the first semiconductor region having an impurity concentration that is higher than the impurity concentration of the first semiconductor layer; a second semiconductor region of a second conductivity type selectively provided in the first semiconductor layer; a second semiconductor layer of the second conductivity type provided on the first side of the first semiconductor layer; a third semiconductor region of the first conductivity type selectively provided in the second semiconductor layer, and having an impurity concentration that is higher than the impurity concentration of the semiconductor substrate; a plurality of trenches penetrating the third semiconductor region and the second semiconductor layer, and reaching the first semiconductor layer, bottoms of the plurality of trenches being in contact with the first semiconductor region; and a gate electrode provided in each of the plurality of trenches, via a gate insulating film. The first semiconductor region is constituted by in a lower first semiconductor region and an upper first semiconductor region that is in contact with a surface of the first semiconductor region and has an impurity concentration that is lower than an impurity concentration of the lower first semiconductor region. The lower first semiconductor region is partially provided between the plurality of trenches and between the second semiconductor regions.

In the embodiment, the second semiconductor region is constituted by a surface region of the second semiconductor region and a lower region of the second semiconductor region closer to the semiconductor substrate than is the surface region of the second semiconductor region, the surface region of the second semiconductor region having an impurity concentration that is higher than an impurity concentration of the lower region of the second semiconductor region, and the surface region of the second semiconductor region having a width that is wider than a width of the lower region of the second semiconductor region.

In the embodiment, the lower first semiconductor region is constituted by a surface region of the lower first semiconductor region and a lower region of the lower first semiconductor region closer to the semiconductor substrate than is the surface region of the lower first semiconductor region, the surface region of the lower first semiconductor region having an impurity concentration that is higher than an impurity concentration of the lower region of the lower first semiconductor region, and the surface region of the lower first semiconductor region having a width that is narrower than a width of the lower region of the lower first semiconductor region.

In the embodiment, the semiconductor device further includes a fourth semiconductor region of the second conductivity type selectively provided in the first semiconductor layer and underlying the bottoms of the plurality of trenches.

According to another embodiment, a method of manufacturing a semiconductor device, includes forming on a front surface of a semiconductor substrate of a first conductivity type, a first semiconductor layer of the first conductivity type and having an impurity concentration that is lower than an impurity concentration of the semiconductor substrate; selectively forming a first semiconductor region of the first conductivity type in a surface layer of the first semiconductor layer, on a first side of the first semiconductor layer, opposite a second side of the first semiconductor layer facing toward the semiconductor substrate, the first semiconductor region having an impurity concentration that is higher than the impurity concentration of the first semiconductor layer; selectively forming a second semiconductor region of a second conductivity type in the first semiconductor layer; forming a second semiconductor layer of the second conductivity type on the first side of the first semiconductor layer; selectively forming in the second semiconductor layer, a third semiconductor region of the first conductivity type and having an purity concentration that is higher than the impurity concentration of the semiconductor substrate; forming a plurality of trenches penetrating the third semiconductor region and the second semiconductor layer, and reaching the first semiconductor layer, bottoms of the plurality of trenches being in contact with the first semiconductor region; and forming a gate electrode in each of the plurality of trenches via a gate insulating film. The first semiconductor region is constituted by a lower first semiconductor region and an upper first semiconductor region in contact with a surface of the lower first semiconductor region and having an impurity concentration that is lower than the impurity concentration of the lower first semiconductor region. Selectively forming the first semiconductor region includes partially forming the lower first semiconductor region between the plurality of trenches and between the second semiconductor regions.

In the embodiment, the second semiconductor region is formed by multi-stage ion implantation having a plurality of acceleration energies, and a dose amount of an ion implantation at a lowest acceleration energy of the plurality of acceleration energies is greater than a dose amount of an ion implantation at another acceleration energy of the plurality of acceleration energies.

In the embodiment, the lower first semiconductor region is formed by multi-stage ion implantation having a plurality of acceleration energies, and a dose amount at a lowest acceleration energy of the plurality of acceleration energies is dose amount is greater than a dose amount of an ion implantation at another acceleration energy.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a part of a structure of a silicon carbide semiconductor device according to a first embodiment at cutting line C-C′ depicted in FIG. 6;

FIG. 2 is a cross-sectional view of a part of the structure of the silicon carbide semiconductor device according to the first embodiment at cutting line D-D′ depicted in FIG. 6;

FIG. 3 is a cross-sectional view of a part of the structure of the silicon carbide semiconductor device according to the first embodiment at cutting line E-E′ depicted in FIG. 6;

FIG. 4 is a cross-sectional view of a part of the structure of the silicon carbide semiconductor device according to the first embodiment at cutting line F-F′ depicted in FIG. 6;

FIG. 5 is an enlarged cross-sectional view of the structure of the silicon carbide semiconductor device according to the first embodiment at a part encompassed by a dotted line in FIG. 4;

FIG. 6 is a sectional plan view of a part of the structure of the silicon carbide semiconductor device according to the first embodiment at cutting line H-H′ depicted in FIG. 1;

FIG. 7 is a perspective view of a part of the structure of the silicon carbide semiconductor device according to the first embodiment;

FIG. 8 is a cross-sectional view of the silicon carbide semiconductor device according to the first embodiment during manufacture;

FIG. 9A is a cross-sectional view of the silicon carbide semiconductor device according to the first embodiment during manufacture;

FIG. 9B is a cross-sectional view of the silicon carbide semiconductor device according to the first embodiment during manufacture;

FIG. 10A is a cross-sectional view of the silicon carbide semiconductor device according to the first embodiment during manufacture;

FIG. 10B is a cross-sectional view of the silicon carbide semiconductor device according to the first embodiment during manufacture;

FIG. 11A is a cross-sectional view of the silicon carbide semiconductor device according to the first embodiment during manufacture;

FIG. 11B is a cross-sectional view of the silicon carbide semiconductor device according to the first embodiment during manufacture;

FIG. 12 is a table of dose amounts for forming a lower-n-type-region surface layer and a lower-n-type-region lower layer;

FIG. 13 is a graph of n-type impurity concentrations at conventional dose amounts;

FIG. 14 is a graph of n-type impurity concentrations formed at dose amounts of the present invention;

FIG. 15 is a table of dose amounts for forming a first p⁺-type-region surface layer and a first p⁺-type-region lower layer;

FIG. 16 is a graph of p-type impurity concentrations at conventional dose amounts;

FIG. 17 is a graph of p-type impurity concentrations formed by the dose amounts of the present invention;

FIG. 18 is a cross-sectional view of a part of the silicon carbide semiconductor device according to a second embodiment at cutting line C-C′ depicted in FIG. 13;

FIG. 19 is a sectional plan view of a structure of a third p⁺-type region of the silicon carbide semiconductor device according to the second embodiment;

FIG. 20 is a cross-sectional view of a part of a structure of a conventional silicon carbide semiconductor device at cutting line A-A′ in FIG. 25;

FIG. 21 is a cross-sectional view of a part of the structure of the conventional silicon carbide semiconductor device at cutting line B-B′ in FIG. 26;

FIG. 22 is a cross-sectional view of a part of the structure of the conventional silicon carbide semiconductor device at cutting line C-C′ in FIG. 25;

FIG. 23 is a cross-sectional view of the structure of the conventional silicon carbide semiconductor device at cutting line D-D′ in FIG. 25;

FIG. 24 is a cross-sectional view of a part of the structure of the conventional silicon carbide semiconductor device at cutting line E-E′ in FIG. 25;

FIG. 25 is a sectional plan view of a part of the structure of the conventional silicon carbide semiconductor device at cutting line G-G′ in FIG. 2; and

FIG. 26 is another sectional plan view of the part of the structure of the conventional silicon carbide semiconductor device at cutting line G-G′ in FIG. 20.

### DESCRIPTION OF EMBODIMENTS

First problems associated with the conventional techniques will be described. In an orthogonal structure in which the second p⁺-type region 104 is orthogonal to the trench, when an interval Z of the second p⁺-type region 104 is increased, the first p⁺-type region 103 and the second p⁺-type region 104 decrease, whereby oxide film electric field at the bottom of the trench 1018 increases. On the other hand, when the interval Z of the second p⁺-type region 104 is decreased, regions forming a channel decrease, whereby parasitic resistance of a junction FET (JFET) region increases. In this manner, in the orthogonal structure, oxide film electric field and parasitic resistance of the JFET region have a tradeoff relationship in which suppressing both the oxide film electric field and the parasitic resistance of the JFET region is difficult.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and will not be repeatedly described.

A semiconductor device according to the present invention is configured using a semiconductor material (hereinafter, wide bandgap semiconductor material) that has a bandgap wider than that of silicon. Here, a structure of a semiconductor device (silicon carbide semiconductor device) that uses, for example, silicon carbide (SiC) as a wide bandgap semiconductor material will be described as an example. Hereinafter, cross-sectional views, a top view, and a perspective view of the silicon carbide semiconductor device according to the first embodiment will be depicted.

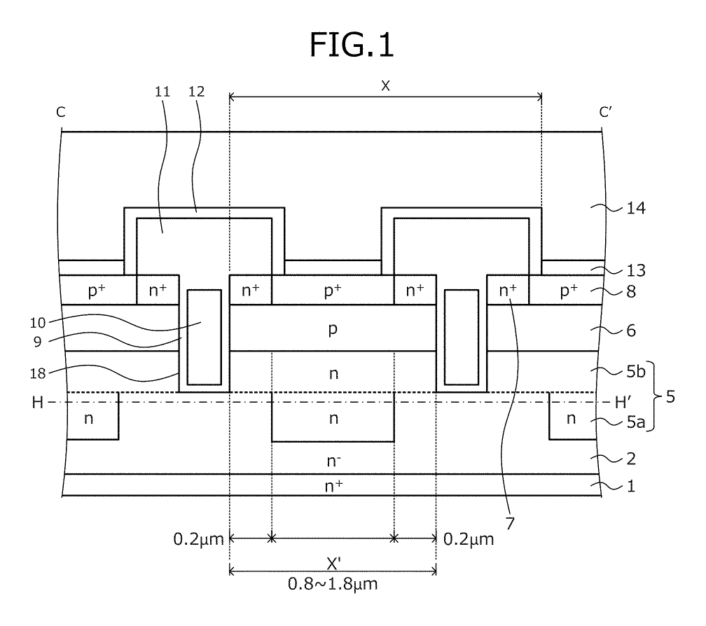

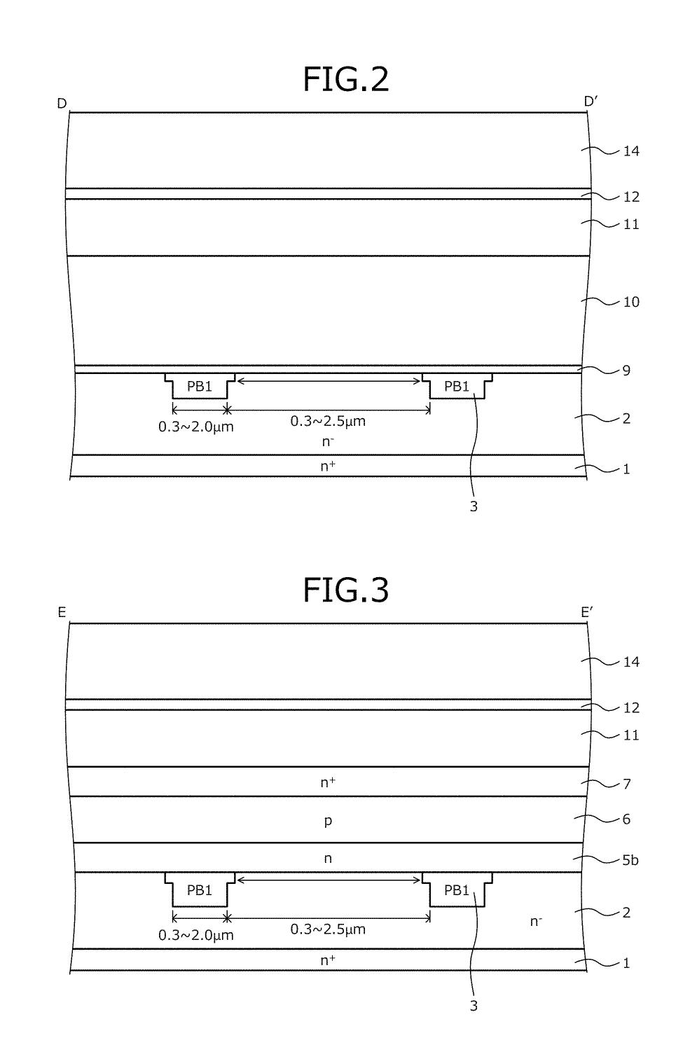

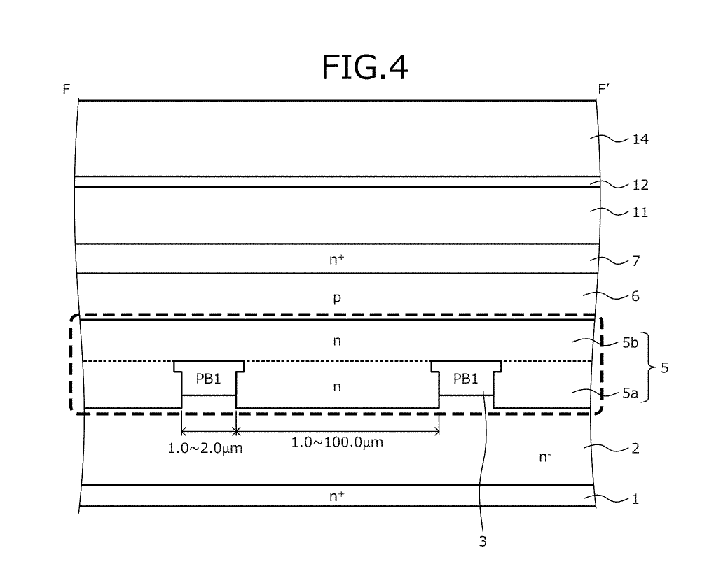

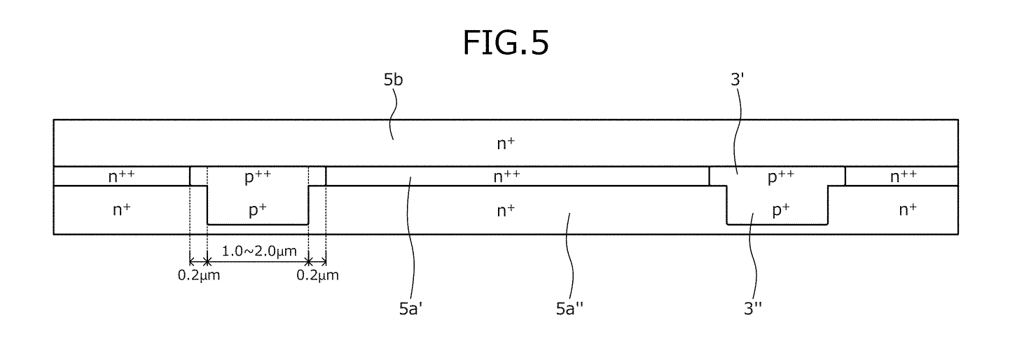

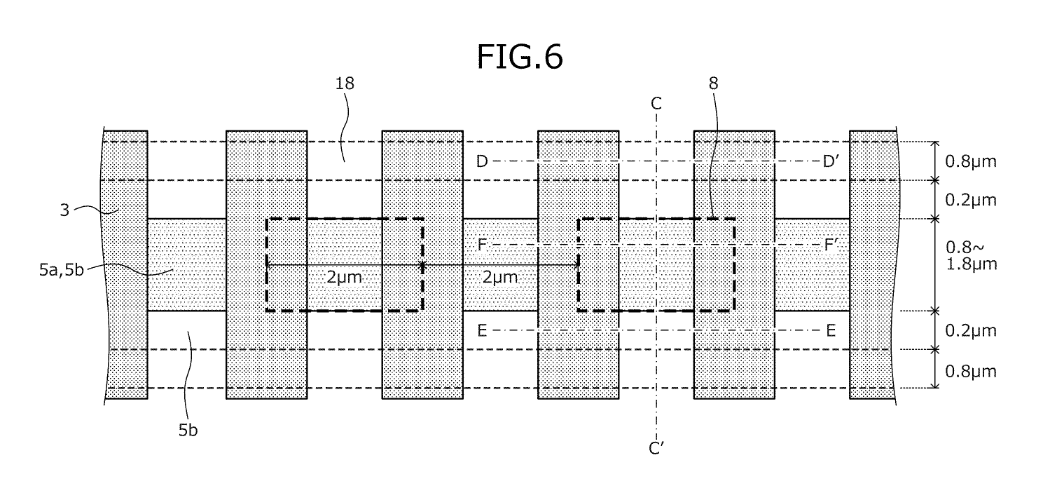

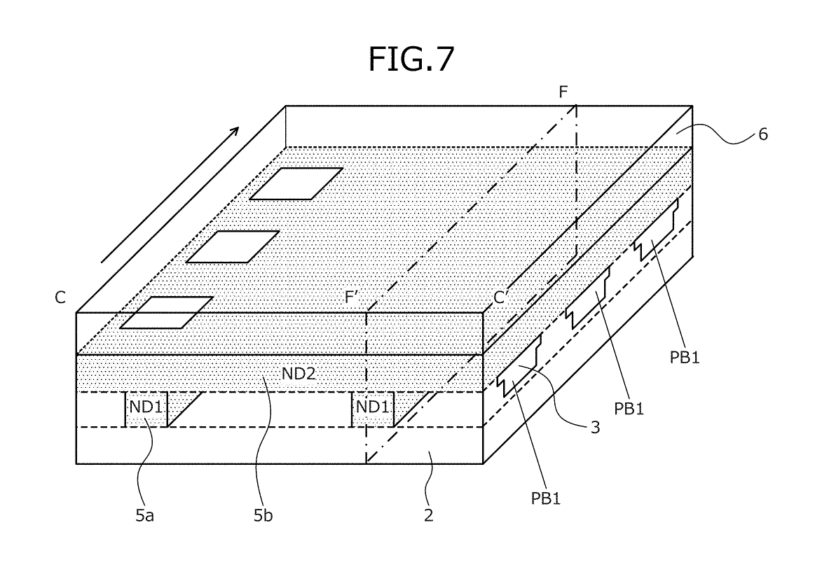

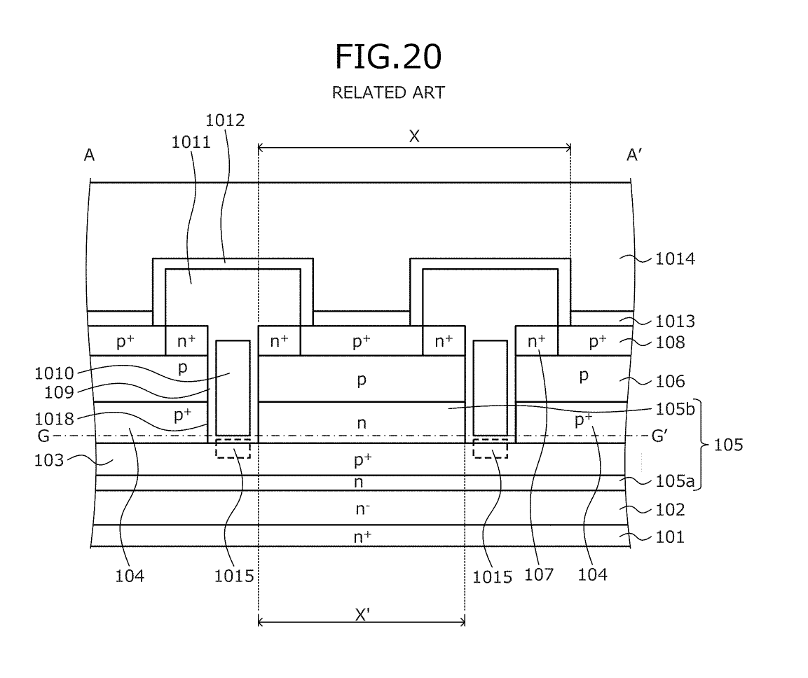

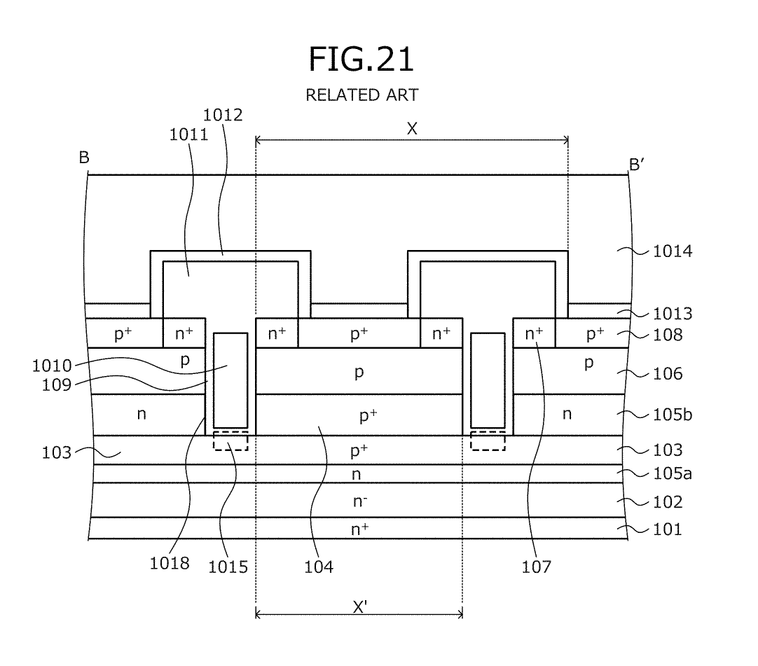

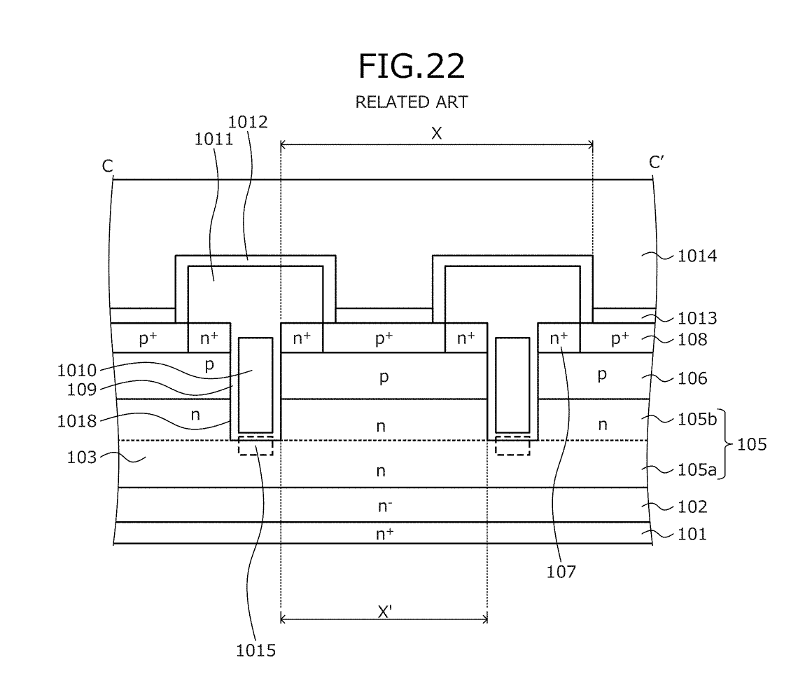

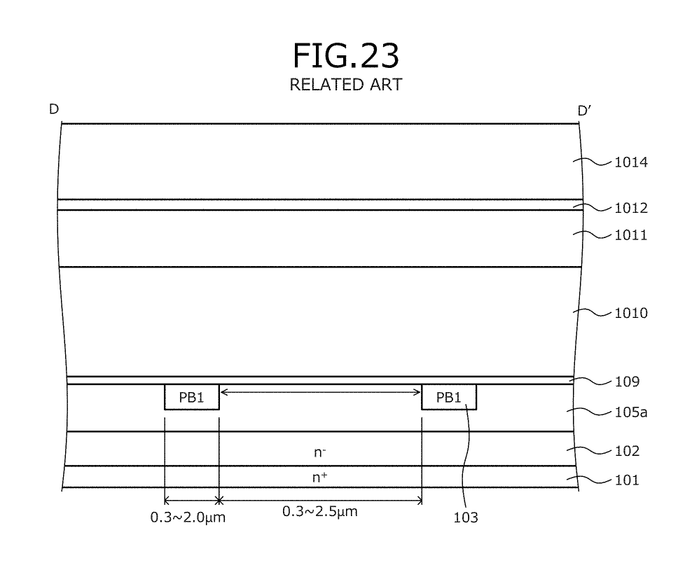

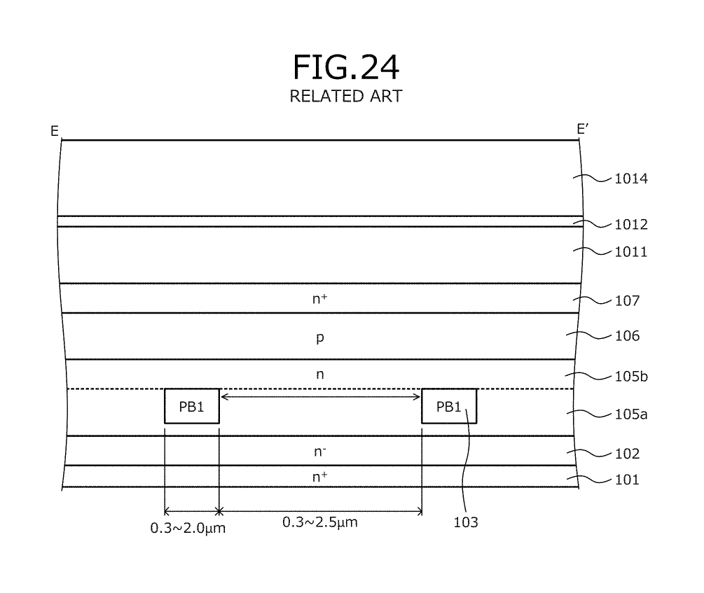

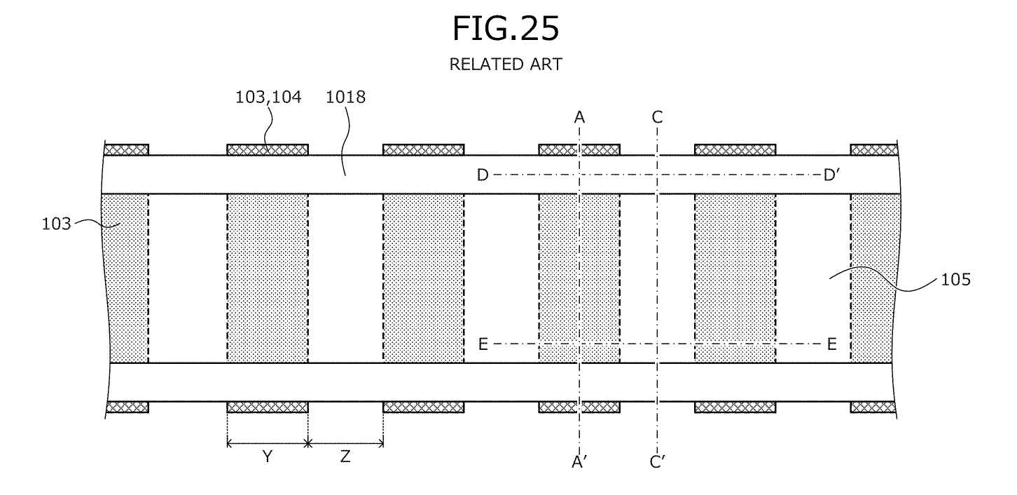

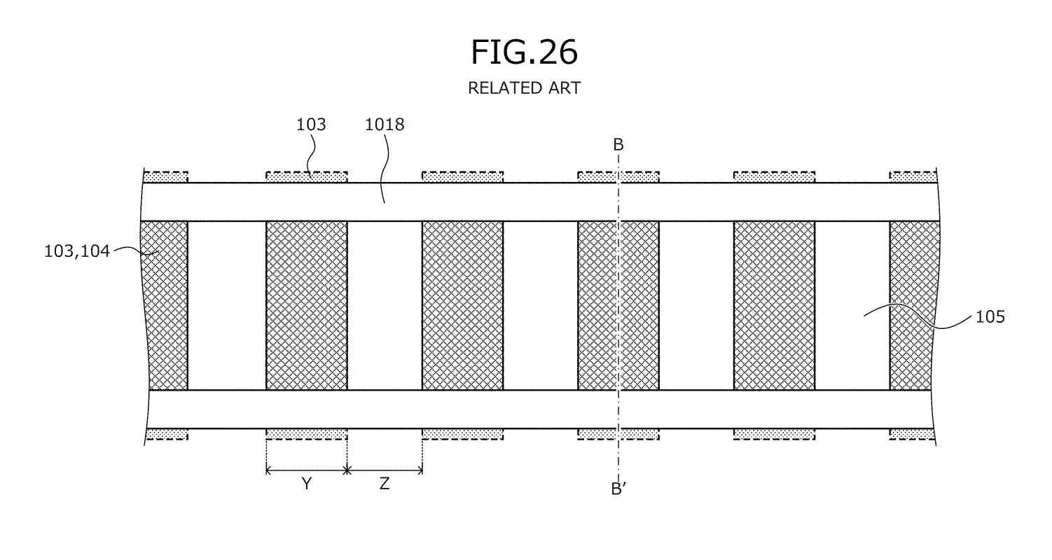

FIG. 1 is a cross-sectional view of a part of a structure of the silicon carbide semiconductor device according to the first embodiment at cutting line C-C′ depicted in FIG. 6. FIG. 2 is a cross-sectional view of a part of the structure of the silicon carbide semiconductor device according to the first embodiment at cutting line D-D′ depicted in FIG. 6. FIG. 3 is a cross-sectional view of a part of the structure of the silicon carbide semiconductor device according to the first embodiment at cutting line E-E′ depicted in FIG. 6. FIG. 4 is a cross-sectional view of a part of the structure of the silicon carbide semiconductor device according to the first embodiment at cutting line F-F′ depicted in FIG. 6. FIG. 5 is an enlarged cross-sectional view of the structure of the silicon carbide semiconductor device according to the first embodiment at a part encompassed by a dotted line in FIG. 4. FIG. 6 is a sectional plan view of a part of the structure of the silicon carbide semiconductor device according to the first embodiment at cutting line H-H′ depicted in FIG. 1. FIG. 7 is a perspective view of a part of the structure of the silicon carbide semiconductor device according to the first embodiment. Here, cross-sectional views of the part according to the first embodiment at cutting line A-A′ depicted in FIG. 25 and the part at cutting line B-B′ depicted in FIG. 26 are similar to the corresponding cross-sectional views of the conventional silicon carbide semiconductor device and therefore, are omitted herein (refer to FIGS. 20 and 21).

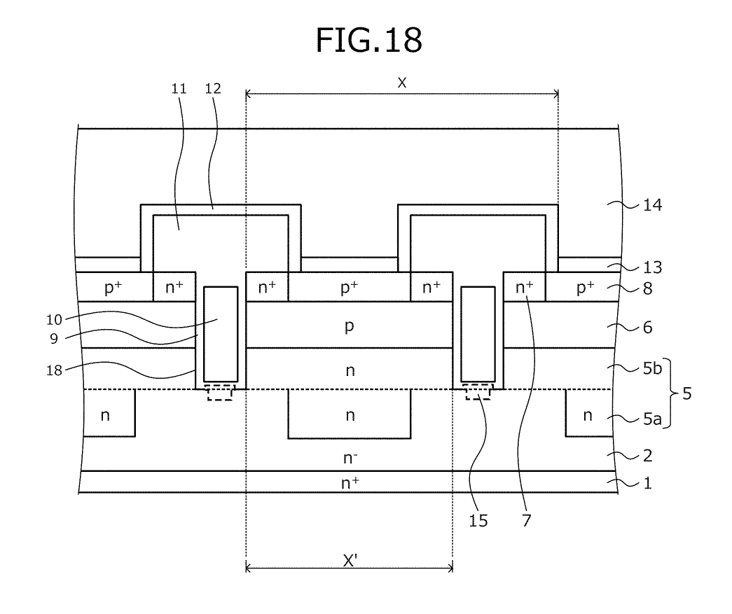

In FIGS. 1 to 5, and 7, only two unit cells (constituent unit of an element) are depicted and other unit cells adjacent to these are not depicted (similarly in FIG. 18). The silicon carbide semiconductor device according to the first embodiment depicted in FIGS. 1 to 7 is a MOSFET that includes a MOS gate at a front surface (surface having a p-type base layer 6) side of a semiconductor base (silicon carbide base: semiconductor chip) containing silicon carbide.

The silicon carbide base is formed by sequentially forming by epitaxial growth on an n⁺-type supporting substrate (semiconductor substrate of a first conductivity type) 1 that contains silicon carbide, silicon carbide layers constituting an n⁻-type drift layer (first semiconductor layer of the first conductivity type) 2 and a p-type base layer (second semiconductor layer of a second conductivity type) 6. The MOS gate includes the p-type base layer 6, an n⁺-type source region (third semiconductor region of the first conductivity type) 7, a p⁺-type contact region 8, a trench 18, a gate insulating film 9, and a gate electrode 10. In particular, in a surface layer of the n⁻-type drift layer 2 on a side thereof toward a source (a source electrode 13), an n-type region (first semiconductor region of the first conductivity type) 5 is provided so as to be in contact with the p-type base layer 6. The n-type region 5 is a so-called current spreading layer (CSL) that reduces carrier spreading resistance.

The n-type region 5 is constituted by a lower n-type region 5a and an upper n-type region 5b in contact with a surface of the lower n-type region 5a. As depicted in FIG. 1, the lower n-type region 5a is provided lower (closer to the n⁺-type silicon carbide substrate 1) than is a bottom of the trench 18 and along a lateral direction of the trench 18, is partially provided between the trench 18 and an adjacent trench 18. Further, as depicted in FIG. 1, regarding the lower n-type region 5a, the n⁻-type drift layer 2 is provided in a region where the lower n-type region 5a is not provided along the lateral direction of the trench 18. Further, as depicted in FIGS. 6 and 7, the lower n-type region 5a is partially provided parallel to a longitudinal direction of the trench 18. As depicted in FIG. 4, along the longitudinal direction of the trench 18, in a region where the lower n-type region 5a is not provided, a first p⁺-type region 3 described hereinafter is provided.

As depicted in FIGS. 1 and 6, for example, the lower n-type region 5a is provided 0.2 μm from a side wall of the trench 18 along the lateral direction of the trench 18, and along the lateral direction of the trench 18, the lower n-type region 5a has a width of 0.8 to 1.8 μm. As depicted in FIGS. 4 and 6, for example, the lower n-type region 5a is provided in contact with the first p⁺-type region 3 described hereinafter, along the longitudinal direction of the trench 18.

In this manner, the n⁻-type drift layer 2 having an impurity concentration lower than that of the lower n-type region 5a is provided between the trenches 18. As a result, spreading of a depletion layer near the bottom of the trenches 18 is facilitated and the oxide film electric field is suppressed while spreading of a depletion layer between the trenches 18 is controlled, whereby JFET parasitic resistance may be suppressed.

Further, as depicted in FIG. 5, a lower-n-type-region surface layer 5a′ provided at a surface and a lower-n-type-region lower layer 5a″ provided at an intermediate part and a lower part constitute the lower n-type region 5a. The lower-n-type-region surface layer 5a′ has an impurity concentration that is higher than that of the lower-n-type-region lower layer 5a″. The lower-n-type-region surface layer 5a′ has a width that is narrower than a width of the lower-n-type-region lower layer 5a″. For example, the lower-n-type-region surface layer 5a′ as a width that is about 0.4 μm narrower than the width of the lower-n-type-region lower layer 5a″.

The upper n-type region 5b is in contact with the lower n-type region 5a and the n⁻-type drift layer 2; and is provided uniformly in a direction parallel to a base front surface (front surface of the silicon carbide base). Further, the upper n-type region 5b has an impurity concentration that is lower than that of the lower n-type region 5a.

In the n⁻-type drift layer 2, the first p⁺-type region 3 is selectively provided; and in the n-type region 5, a second p⁺-type region is selectively provided. The first p⁺-type region 3, similar to a conventional example, partially underlies the bottom of the trench 18 and is orthogonal to the trench 18 (refer to FIG. 6). The first p⁺-type region 3 is provided at a depth not reaching the n⁺-type silicon carbide substrate 1.

Further, as depicted in FIG. 5, a first p⁺-type-region surface layer 3′ at a surface and a first-p⁺-type-region lower layer 3″ provided at an intermediate part and a lower part constitute the first p⁺-type region 3. The first-p⁺-type-region surface layer 3′ has an impurity concentration that is higher than that of the first-p⁺-type-region lower layer 3″. The first-p⁺-type-region surface layer 3′ has a width that is wider than that of the first-p⁺-type-region lower layer 3″ by the amount that the lower-n-type-region surface layer 5a′ is narrower than the lower-n-type-region lower layer 5a″. For example, as depicted in FIGS. 2 to 3, along the longitudinal direction of the trench 18, the width of the first-p⁺-type-region lower layer 3″ is 0.3 to 2.0 μm and the width of the first-p⁺-type-region surface layer 3′ is about 0.4 μm wider than that of the first-p⁺-type-region lower layer 3″. Further, for example, the first p⁺-type region 3 is provided separated by 0.3 to 2.5 μm. As depicted in FIG. 6, for example, along the longitudinal direction of the trench 18, the first p⁺-type region 3 is provided at intervals of 2 μm.

In this manner, the width of the first p⁺-type-region surface layer 3′ at the bottom of the trench 18 is wider than the width of the first p⁺-type-region lower layer 3″. As a result, spreading of the depletion layer near the bottom of the trench 18 is facilitated and the oxide film electric field is suppressed. In this case, spreading of the depletion layer between the trenches 18 is facilitated, whereby the JFET parasitic resistance slightly increases but exerts minimal influence because a distance with respect to the current path is short. Further, the width of the lower-n-type-region surface layer 5a′ is narrower than the width of the lower-n-type-region lower layer 5a″, whereby the JFET parasitic resistance, which slightly increases more than above, may be suppressed.

The second p⁺-type region, similar to the conventional example, is selectively provided between (mesa part) adjacent trenches 18 (refer to FIG. 21). Provision of the first p⁺-type region 3 enables a pn junction between the first p⁺-type region 3 and the n-type region 5 to be formed near the bottoms of the trenches 18. The first p⁺-type region 3 has an impurity concentration that is higher than that of the p-type base layer 6.

Further, inside the p-type base layer 6, the n⁺-type source region 7 and the p⁺-type contact region 8 are selectively provided so as to be in contact with each other. A depth of the p⁺-type contact region 8, for example, may be equal to or may be deeper than the depth of the n⁺-type source region 7.

The trench 18 penetrates the n⁺-type source region 7 and the p-type base layer 6 from the base front surface and reaches the n-type region 5. In the trench 18, the gate insulating film 9 is provided along side walls of the trench 18, and on the gate insulating film 9, the gate electrode 10 is provided. An end of the gate electrode 10 toward the source may or may not protrude from the base front surface. The gate electrode 10 is electrically connected at a non-depicted part to a gate pad (not depicted). The interlayer insulating film 11 is provided on the base front surface overall so as to cover the gate electrode 10 embedded in the trench 18. In FIG. 1, X represents the cell pitch, which is 2.0 to 3.0 μm, and X′ represents a distance between respective side walls of the adjacent trenches 18, which is 0.8 to 1.8 μm.

The source electrode 13 is in contact with the n⁺-type source region 7 and the p⁺-type contact region 8 through a contact hole opened in the interlayer insulating film 11. The source electrode 13 is electrically insulated from the gate electrode 10 by the interlayer insulating film 11. Between the source electrode 13 and the interlayer insulating film 11, for example, a barrier metal 12 may be provided that prevents metal atoms from diffusing from the source electrode 13 toward the gate electrode 10. A source electrode pad 14 is provided on the source electrode 13. At a rear surface (rear surface of the n⁺-type silicon carbide substrate 1 constituting an n⁺-type drain region) of the silicon carbide base, a drain electrode (not depicted) is provided.

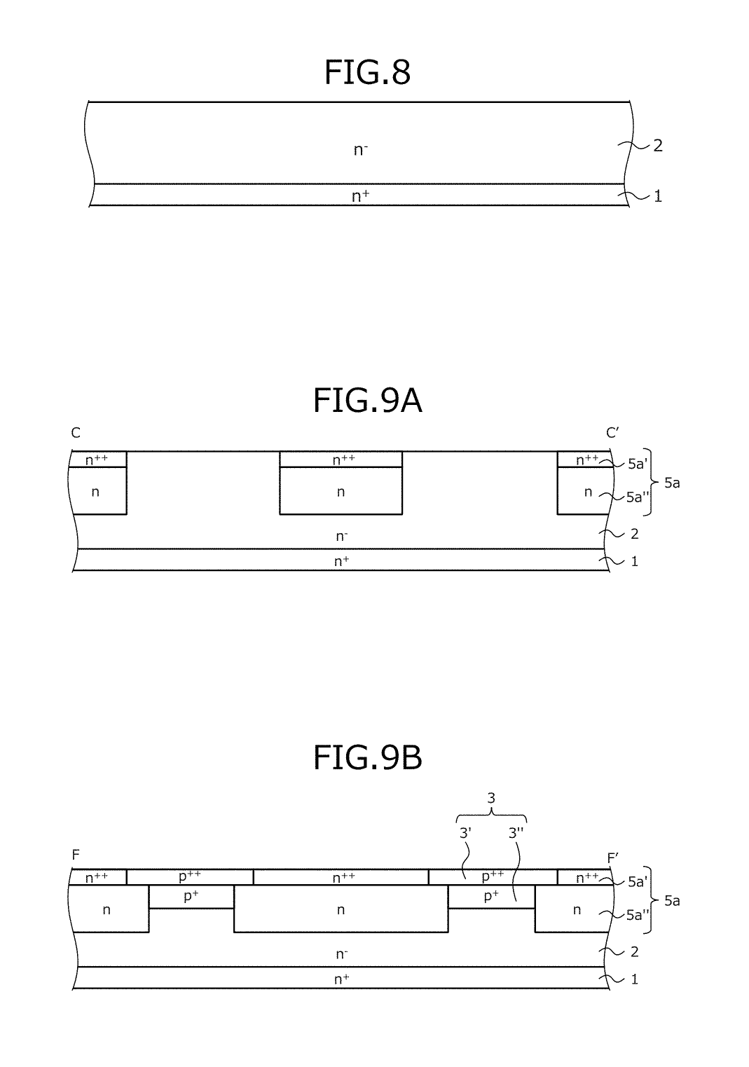

A method of manufacturing the semiconductor device according to the first embodiment will be described. FIGS. 8, 9A, 9B, 10A, 10B, 11A, and 11B are cross-sectional views of the silicon carbide semiconductor device according to the first embodiment during manufacture. First, the n⁺-type silicon carbide substrate 1 constituting the n⁺-type drain region is prepared. Next, on the front surface of the n⁺-type silicon carbide substrate 1, the n⁻-type drift layer 2 is formed by epitaxial growth. For example, conditions of the epitaxial growth for forming the n⁻-type drift layer 2 may be set so that the impurity concentration of the n⁻-type drift layer 2 becomes about 3×10¹⁵/cm³. The state up to here is depicted in FIG. 8.

Next, by photolithography and ion implantation of a p-type impurity, in a surface layer of the n⁻-type drift layer 2, the lower-n-type-region lower layer 5a″ and the lower-n-type-region surface layer 5a′ are selectively formed. At this time, the lower-n-type-region surface layer 5a′ is formed having an impurity concentration that is higher than the impurity concentration of the lower-n-type-region lower layer 5a″. Further, the lower-n-type-region surface layer 5a′ is formed to have a width that is wider than the width of the lower-n-type-region lower layer 5a″. For example, dose amounts during ion implantations for forming the lower-n-type-region lower layer 5a″ and the lower-n-type-region surface layer 5a′ may be set so that the respective impurity concentrations are about 1×10¹⁷/cm³ and 2×10¹⁷/cm³, respectively. The lower n-type region 5a is a part of the n-type region 5.

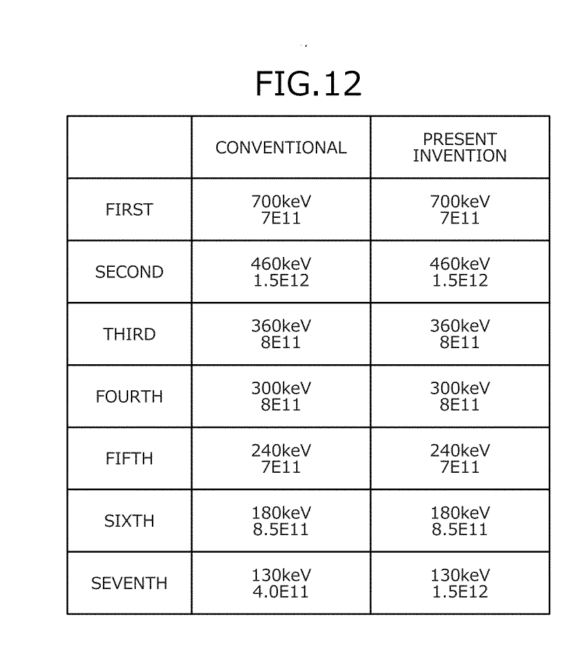

Here, the ion implantations for the lower-n-type-region lower layer 5a″ and the lower-n-type-region surface layer 5a′ will be described. FIG. 12 is a table of dose amounts for forming the lower-n-type-region surface layer and the lower-n-type-region lower layer. In FIG. 12, “conventional” depicts acceleration energies and dose amounts in conventional ion implantations for forming the n-type region and “present invention” depicts acceleration energies and dose amounts in the ion implantations for forming the lower-n-type-region lower layer 5a″ and the lower-n-type-region surface layer 5a′ of the present invention. As depicted in FIG. 12, in the present invention, a seventh stage dose amount is 1.5×10¹²/cm² and greater than a conventional seventh stage dose amount of 4.0×10¹¹/cm². Further, the impurity concentration of the lower-n-type-region surface layer 5a′ is increased, whereby the seventh stage dose amount when the acceleration energy is the lowest is greater than first to sixth stage dose amounts.

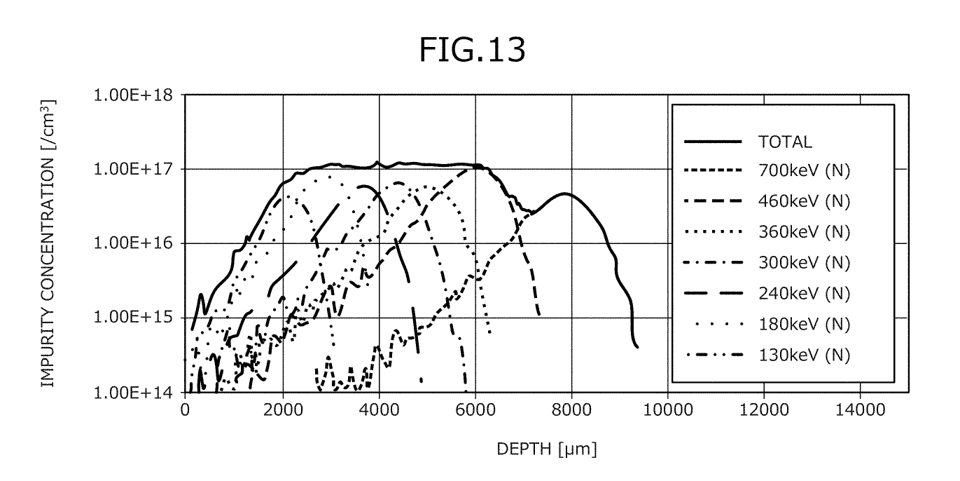

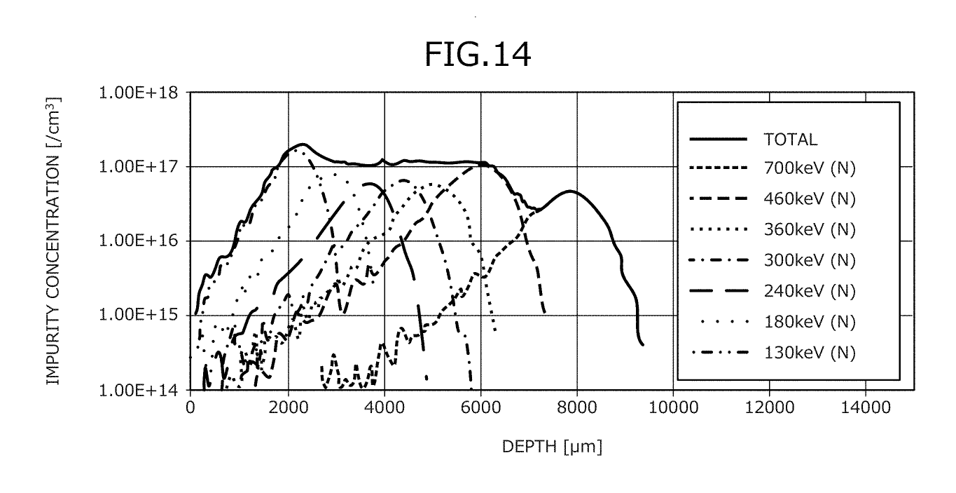

FIG. 13 is a graph of n-type impurity concentrations at the conventional dose amounts. The impurity concentrations are those of the n-type region formed at the conventional acceleration energies and dose amounts depicted in FIG. 12. The horizontal axis represents the depth of the surface and is indicated in units of μm. The vertical axis represents the n-type impurity concentration and is indicated in units of/cm³. FIG. 14 is a graph of the n-type impurity concentrations formed at the dose amounts of the present invention. The n-type impurity concentrations are the impurity concentrations of the n-type region formed by the acceleration energies and dose amounts of the present invention depicted in FIG. 12. The horizontal axis and the vertical axis are similar to those in FIG. 13. As depicted in FIG. 13, with the conventional dose amounts, the impurity concentration of the n-type region is uniform. However, as depicted in FIG. 14, with the dose amounts of the present invention, the impurity concentration of the lower-n-type-region surface layer 5a′ is higher than the impurity concentration of the lower-n-type-region lower layer 5a″.

Next, by photolithography and ion implantation of a p-type impurity, the first p⁺-type-region lower layer 3″ and the first p⁺-type-region surface layer 3′ are selectively formed in the surface layer of the n⁻-type drift layer 2. At this time, the first p⁺-type-region surface layer 3′ is formed having an impurity concentration that is higher than the impurity concentration of the first p⁺-type-region lower layer 3″. Further, the first p⁺-type-region surface layer 3′ is formed having a width that is wider than the width of the first p⁺-type-region lower layer 3″. For example, dose amounts during ion implantations for forming the first p⁺-type-region lower layer 3″ and the first p⁺-type-region surface layer 3′ may be set so that respective impurity concentrations thereof are about 5×10¹⁸/cm³ and 2×10²⁰/cm³, respectively. The state up to here is depicted in FIGS. 9A and 9B. Here, FIG. 9A is a cross-sectional view of a part at cutting line C-C′ depicted in FIG. 6. FIG. 9B is a cross-sectional view of a part at cutting line F-F′ depicted in FIG. 6.

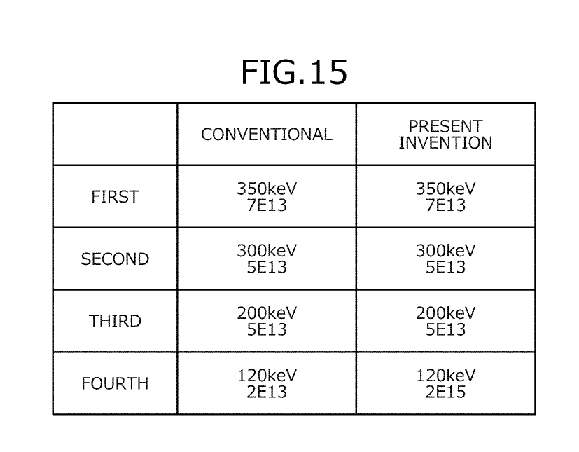

Here, ion implantations for the first p⁺-type-region lower layer 3″ and the first p⁺-type-region surface layer 3′ will be described. FIG. 15 is a table of dose amounts for forming the first p⁺-type-region surface layer 3′ and the first p⁺-type-region lower layer 3″. In FIG. 15, “conventional” indicates acceleration energies and dose amounts of conventional ion implantations for forming a p⁺-type region, and “present invention” indicates acceleration energies and dose amounts of ion implantations of the present invention for forming the first p⁺-type-region surface layer 3′ and the first p⁺-type-region lower layer 3″. As depicted in FIG. 15, in the present invention, a fourth-stage dose amount is 2.0×10¹⁵/cm² and greater than a conventional fourth-stage dose amount of 2.0×10¹³/cm². Further, the impurity concentration of the first p⁺-type-region surface layer 3′ is high and therefore, the fourth-stage dose amount for which the acceleration energy is the lowest is greater than first to third-stage dose amounts.

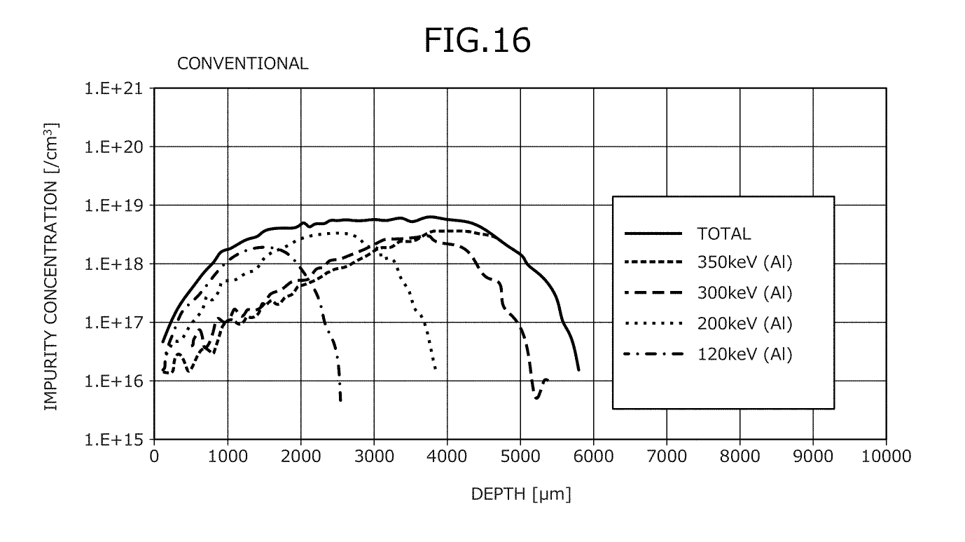

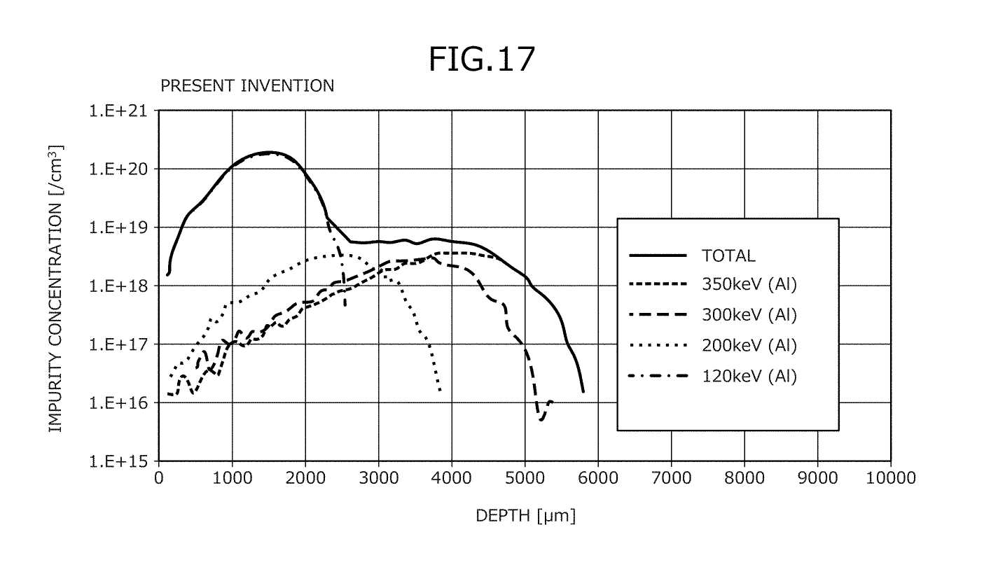

FIG. 16 is a graph of p-type impurity concentrations at conventional dose amounts. The impurity concentrations are those of the p⁺-type region formed by the conventional acceleration energies and dose amounts depicted in FIG. 15. In FIG. 16, the horizontal axis represents the depth from the surface in units of μm, and the vertical axis represents the p-type impurity concentration in units/cm³. Further, FIG. 17 is a graph of the p-type impurity concentrations formed by the dose amounts of the present invention. The impurity concentrations in FIG. 17 are those of the first p⁺-type-region lower layer 3″ and the first p⁺-type-region surface layer 3′ formed by the acceleration energies and dose amounts of the present invention, and the horizontal and vertical axes therein are similar to those in FIG. 16. As depicted in FIG. 16, at the conventional dose amounts, the impurity concentration of the p-type region is substantially uniform. As depicted in FIG. 17, at the dose amounts of the present invention, the first p⁺-type-region surface layer 3′ is formed having an impurity concentration that is higher than the impurity concentration of the first p⁺-type-region lower layer 3″.

Next, on the lower n-type region 5a and the first p⁺-type region 3, the upper n-type region 5b is formed by epitaxial growth. For example, conditions of the epitaxial growth for forming the upper n-type region 5b may be set such that the impurity concentration of the upper n-type region 5b becomes about equal to the impurity concentration of the lower-n-type-region lower layer 5a″. The upper n-type region 5b is a part of the n-type region 5 and combined with the lower n-type region 5a and the upper n-type region 5b, forms the n-type region 5.

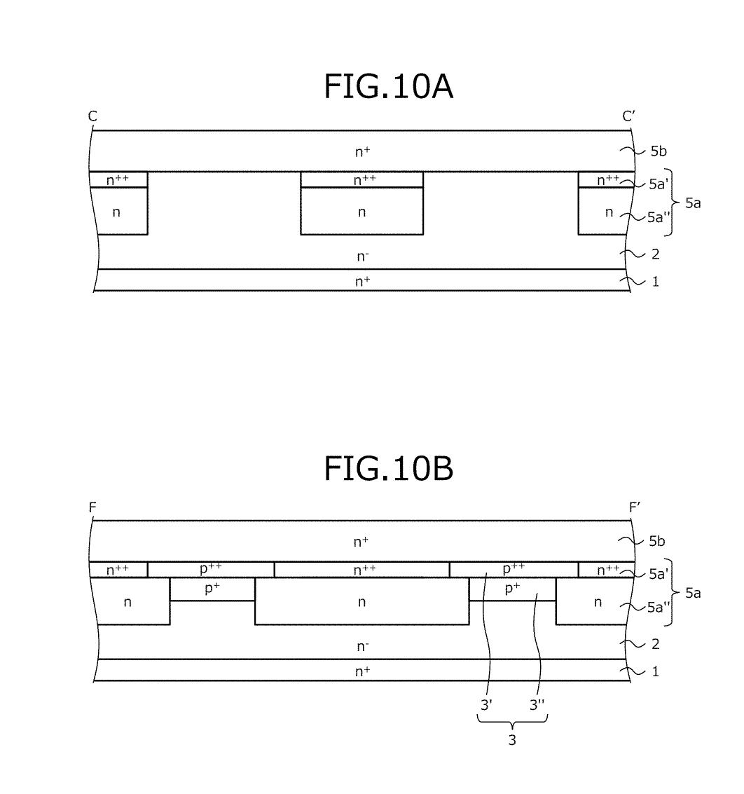

Next, by photolithography and ion implantation of a p-type impurity, in a surface layer of the upper n-type region 5b, the second p⁺-type region (not depicted) is selectively formed. For example, a dose amount during ion implantation for forming the second p⁺-type region may be set so that the impurity concentration becomes about equal to that of the first p⁺-type-region lower layer 3″. The state up to here is depicted in FIGS. 10A and 10B. Here, FIG. 10A is a cross-sectional view of a part at cutting line C-C′ depicted in FIG. 6. FIG. 10B is a cross-sectional view of a part at cutting line F-F′ depicted in FIG. 6.

Next, on the upper n-type region 5b and the second p⁺-type region, the p-type base layer 6 is formed by epitaxial growth. For example, conditions of the epitaxial growth for forming the p-type base layer 6 may be set so that the impurity concentration of the p-type base layer 6 becomes about 4×10¹⁷/cm³. Next, by photolithography and ion implantation of a n-type impurity, in a surface layer of the p-type base layer 6, the n⁺-type source region 7 is selectively formed. For example, a dose amount during ion implantation for forming the n⁺-type source region 7 may be set so that an impurity concentration of the n⁺-type source region 7 becomes about 3×10²⁰/cm³.

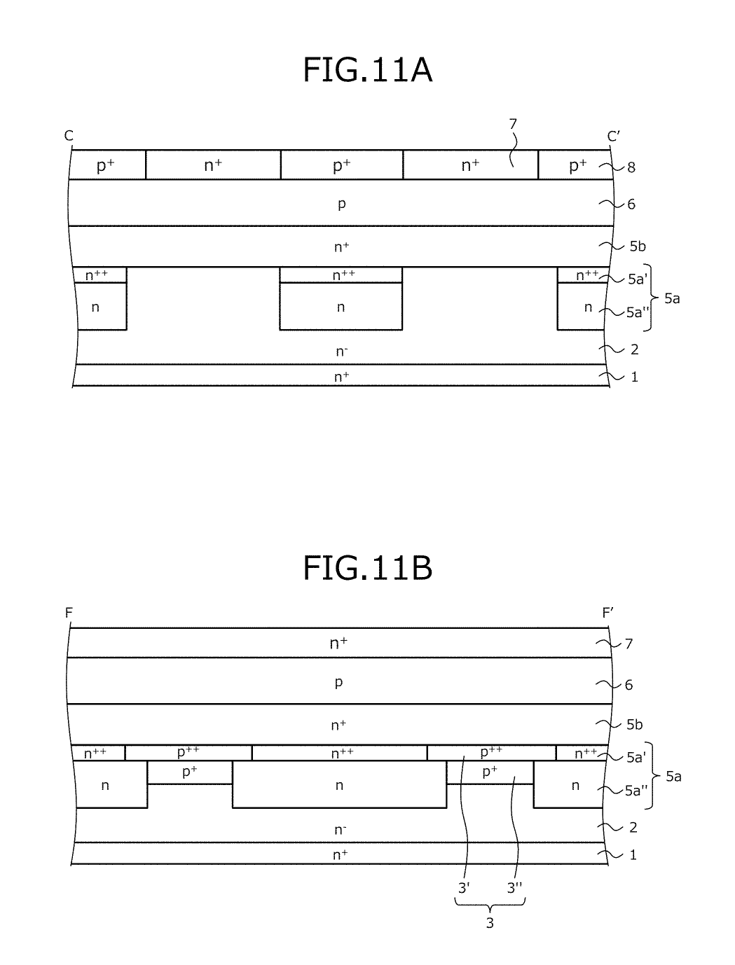

Next, by photolithography and ion implantation of a p-type impurity, in the surface layer of the p-type base layer 6, the p⁺-type contact region 8 is selectively formed so as to be in contact with the n⁺-type source region 7. For example, a dose amount during ion implantation for forming the p⁺-type contact region 8 may be set so that the impurity concentration of the p⁺-type contact region 8 becomes about 3×10²⁰/cm³. A sequence in which the n⁺-type source region 7 and the p⁺-type contact region 8 are formed may be interchanged. After all of the ion implantations have been completed, activation annealing is performed. The state up to here is depicted in FIGS. 11A and 11B. Here, FIG. 11A is a cross-sectional view of a part at cutting line C-C′ depicted in FIG. 6. FIG. 11B is a cross-sectional view of a part at cutting line F-F′ depicted in FIG. 6.

Next, by photolithography and etching, the trench 18 is formed penetrating the n⁺-type source region 7 and the p-type base layer 6 to reach the n-type region 5. Further, an oxide film is used as a mask at the time of trench formation. After the trench etching, isotropic etching for removing damage of the trench 18 and hydrogen annealing for rounding corners of an opening of the trench 18 and the bottom of the trench 18 may be performed. Any one of the isotropic etching and the hydrogen annealing may be performed. Further, the hydrogen annealing may be performed after the isotropic etching is performed.

Next, along the front surface of the silicon carbide base and an inner wall of the trench 18, the gate insulating film 9 is formed. Next, for example, poly-silicon is deposited and etched so as to be embedded in the trench 18, whereby the poly-silicon is left in the trench 18 to thereby form the gate electrode 10. At this time, etching may be performed so that the poly-silicon remains inside below a base surface part, or patterning and etching may be performed, whereby the poly-silicon protrudes outside from the base surface part.

Next, the interlayer insulating film 11 is formed on the entire front surface of the silicon carbide base so as to cover the gate electrode 10. The interlayer insulating film 11, for example, may be formed by a none-doped silicate glass (NSG), a phosphosilicate glass (PSG), a borophosphosilicate glass (BPSG), a high temperature oxide (HTO), or a combination thereof. Next, the interlayer insulating film 11 and the gate insulating film 9 are patterned and a contact hole is formed, exposing the n⁺-type source region 7 and the p⁺-type contact region 8.

Next, the barrier metal 12 is formed and patterned so as to cover the interlayer insulating film 11 and again expose the n⁺-type source region 7 and the p⁺-type contact region 8. Next, the source electrode 13 is formed so as to be in contact with the n⁺-type source region 7. The source electrode 13 may be formed so as to cover the barrier metal, or may be left only in the contact hole.

Next, the source electrode pad 14 is formed so as to be embedded in the contact hole. A part of a metal layer deposited to form the source electrode pad 14 may be used as a gate pad. At the rear surface of the n⁺-type silicon carbide substrate 1, a metal film such as a nickel (Ni) film, a titanium (Ti) film, etc. is formed at a contact part of the drain electrode by sputtering deposition, etc. The metal film may be a stacked combination of one or more Ni films and Ti films. Thereafter, annealing such as rapid thermal annealing (RTA), etc. is performed converting the metal film into a silicide and forming an ohmic contact. Thereafter, for example, a thick film such as a stacked film in which a Ti film, a Ni film, and a gold (Au) are sequentially stacked is formed by electron beam (EB) deposition, forming the drain electrode.

In the epitaxial growth and ion implantations above, as an n-type impurity (n-type dopant), for example, nitrogen (N), phosphorus (P), arsenic (As), antimony (Sb), etc. that are n-types with respect to silicon carbide is used. As a p-type impurity (p-type dopant), for example, boron (B), aluminum (Al), gallium (Ga), indium (In), thallium (Tl), etc. that are p-types with respect to silicon carbide is used. In this manner, the MOSFET depicted in FIGS. 1 to 7 is completed.

As described according to the first embodiment, the lower n-type region, is partially arranged between the trenches along the lateral direction of the trenches. As a result, in the mesa part, the n⁻-type drift layer having an impurity concentration that is lower than that of the lower n-type region is provided. Therefore, spreading of a depletion layer near the bottom of the trenches is facilitated, electric field (oxide film electric field) applied to an oxide film such as the gate insulating film is suppressed, and spreading of a depletion layer of the mesa part is suppressed, whereby the JFET parasitic resistance is suppressed, enabling the trade-off relationship of the oxide film electric field and the parasitic resistance of the JFET region to be improved.

Further, the width of the surface layer of the first p⁺-type region is wider than the width of the lower layer of the first p⁺-type region. As a result, spreading of a depletion layer near the bottom of the trenches is facilitated and the oxide film electric field is suppressed. Spreading of a depletion layer of the mesa part is also suppressed and while the JFET parasitic resistance increases slightly, the distance with respect to the current path is short and therefore, there is minimal effect. Since the width of the surface layer of the lower n-type region is narrower than the width of the lower layer of the n-type region, the JFET parasitic resistance that slightly increases may be suppressed as described above.

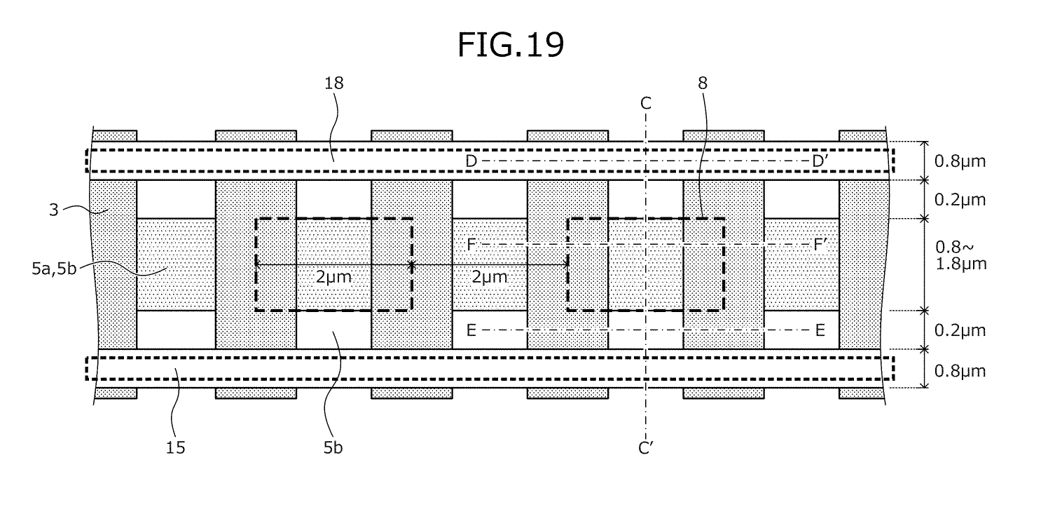

A structure of the semiconductor device according to a second embodiment will be described. FIG. 18 is a cross-sectional view of a part of the silicon carbide semiconductor device according to the second embodiment at cutting line C-C′ depicted in FIG. 13. FIG. 19 is a sectional plan view of a structure of a third p⁺-type region 15 of the silicon carbide semiconductor device according to the second embodiment. The silicon carbide semiconductor device according to the second embodiment differs from the silicon carbide semiconductor device according to the first embodiment in that the third p⁺-type region (fourth semiconductor region of the second conductivity type) 15 is provided at the bottom of the trench 18.

The third p⁺-type region 15 is provided at a deep position closer to the drain than is an interface of the upper n-type region 5b and the n⁻-type drift layer 2. Provision of the third p⁺-type region 15 enables a pn junction between the third p⁺-type region 15 and the n⁻-type drift layer 2 to be formed near the bottom of the trench 18. Further, the third p⁺-type region 15 has an impurity concentration that is higher than the impurity concentration of the p-type base layer 6.

Here, the third p⁺-type region 15 has a width that is equal to or less than the width of the trench 18. Therefore, the third p⁺-type region 15 may be formed by self-alignment, i.e., may be formed using the mask for forming the trench 18. In this manner, since the third p⁺-type region 15 is formed using the same mask, deviation (misalignment) of the formation positions the third p⁺-type region 15 and the trench 18 do not occur.

A method of manufacturing the semiconductor device according to the second embodiment will be described. First, similarly to the first embodiment, the n⁺-type silicon carbide substrate 1 is prepared and processes up through forming the trench 18 are sequentially performed (refer to FIGS. 8 to 11).

Next, the mask used at the time of trench formation is used and by ion implantation of a p-type impurity, the third p⁺-type region 15 is selectively formed at the bottoms of the trenches 18. For example, a dose amount during ion implantation for forming the third p⁺-type region 15 may be set so that the impurity concentration of the third p⁺-type region 15 becomes about equal to that of the second p⁺-type region. Thereafter, similarly to the first embodiment, the process of forming the gate insulating film 9 and subsequent processes are sequentially performed, whereby the MOSFET depicted in FIGS. 18 and 19 is completed.

As described, according to the second embodiment, effects similar to those of the first embodiment are obtained. Further, provision of the third p⁺-type region enables a pn junction between the third p⁺-type region and the type drift layer to be formed, whereby electric field concentrates at the pn junction, enabling a concentration of electric field at the bottom of the trench to be mitigated.

In the embodiments of the present invention, various modifications within a range not departing from the spirit of the invention are possible. For example, dimensions, impurity concentrations, etc. of regions may be variously set according to required specifications. Further, while a MOSFET is described as an example in the embodiments, without limitation hereto, wide application to various silicon carbide semiconductor devices in which conduction and shutoff of current is performed by gate driving control based on a predetermined gate threshold voltage is possible. As a silicon carbide semiconductor device under gate driving control, insulated gate bipolar transistor (IGBT) may be given as an example. Further, in the embodiments, while a case in which silicon carbide is used as a wide bandgap semiconductor material, application is possible to a wide bandgap semiconductor material other than silicon carbide such as gallium nitride (GaN). Further, in the embodiments, while the first conductivity type is assumed as an n-type and the second conductivity type is assumed as a p-type, the present invention is similarly implemented when the first conductivity type is a p-type and the second conductivity type is an n-type.

According to the embodiments of the present invention, the lower n-type region (lower first semiconductor region) is partially provided between the trenches along the lateral direction of the trenches. As a result, in the mesa part, the n⁻-type drift layer (first semiconductor layer of the first conductivity type) having an impurity concentration lower than that of the lower n-type region is provided. As a result, spreading of a depletion layer near the bottom of the trenches is facilitated, oxide film electric field is suppressed, and spreading of a depletion layer in the mesa part is suppressed, whereby the JFET parasitic resistance is suppressed, enabling the trade-off relationship of the oxide film electric field and parasitic resistance of the JFET region to be improved.

Further, the width of the surface layer of the first p⁺-type region (second semiconductor region) is wider than the width of the lower layer of the first p⁺-type region. As a result, spreading of a depletion layer near the bottom of trenches is facilitated and oxide film electric field is suppressed. Further, spreading of a depletion layer in the mesa part is facilitated, whereby the JFET parasitic resistance, which slightly increases, has no adverse effects because the distance with respect to the current path is short. The width of the surface layer of the lower n-type region is narrower than the width of the lower layer of the lower n-type region, whereby the JFET parasitic resistance, which slightly increases, may be suppressed as described above.

The semiconductor device and the method of manufacturing a semiconductor device according to the embodiments of the present invention achieve an effect in that the trade-off relationship of oxide film electric field and parasitic resistance of the JFET region may be improved.

As described, the silicon carbide semiconductor device and the silicon carbide method of manufacturing a semiconductor device according to the embodiments of the present invention are useful for power semiconductor devices used in power converting equipment, and power supply devices such as in various industrial machines; and are particularly suitable for silicon carbide semiconductor devices having a trench gate structure.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor substrate of a first conductivity type;
a first semiconductor layer of the first conductivity type provided on a front surface of the semiconductor substrate, and having an impurity concentration that is lower than an impurity concentration of the semiconductor substrate;
a first semiconductor region of the first conductivity type selectively provided in a surface layer of the first semiconductor layer on a first side of the first semiconductor layer, opposite a second side of the first semiconductor layer facing toward the semiconductor substrate, the first semiconductor region having an impurity concentration that is higher than the impurity concentration of the first semiconductor layer;
a second semiconductor region of a second conductivity type selectively provided in the first semiconductor layer;
a second semiconductor layer of the second conductivity type provided on the first side of the first semiconductor layer;
a third semiconductor region of the first conductivity type selectively provided in the second semiconductor layer, and having an impurity concentration that is higher than the impurity concentration of the semiconductor substrate;
a plurality of trenches penetrating the third semiconductor region and the second semiconductor layer, and reaching the first semiconductor layer, bottoms of the plurality of trenches being in contact with the first semiconductor region; and
a gate electrode provided in each of the plurality of trenches, via a gate insulating film, wherein
the first semiconductor region is constituted by in a lower first semiconductor region and an upper first semiconductor region that is in contact with a surface of the first semiconductor region and has an impurity concentration that is lower than an impurity concentration of the lower first semiconductor region, and
the lower first semiconductor region is partially provided between the plurality of trenches and between the second semiconductor regions.

2. The semiconductor device according to claim 1, wherein
the second semiconductor region is constituted by a surface region of the second semiconductor region and a lower region of the second semiconductor region closer to the semiconductor substrate than is the surface region of the second semiconductor region, the surface region of the second semiconductor region having an impurity concentration that is higher than an impurity concentration of the lower region of the second semiconductor region, and the surface region of the second semiconductor region having a width that is wider than a width of the lower region of the second semiconductor region.

3. The semiconductor device according to claim 1, wherein
the lower first semiconductor region is constituted by a surface region of the lower first semiconductor region and a lower region of the lower first semiconductor region closer to the semiconductor substrate than is the surface region of the lower first semiconductor region, the surface region of the lower first semiconductor region having an impurity concentration that is higher than an impurity concentration of the lower region of the lower first semiconductor region, and the surface region of the lower first semiconductor region having a width that is narrower than a width of the lower region of the lower first semiconductor region.

4. The semiconductor device according to claim 1, further comprising
a fourth semiconductor region of the second conductivity type selectively provided in the first semiconductor layer and underlying the bottoms of the plurality of trenches.

5. A method of manufacturing a semiconductor device, the method comprising:
forming on a front surface of a semiconductor substrate of a first conductivity type, a first semiconductor layer of the first conductivity type and having an impurity concentration that is lower than an impurity concentration of the semiconductor substrate;
selectively forming a first semiconductor region of the first conductivity type in a surface layer of the first semiconductor layer, on a first side of the first semiconductor layer, opposite a second side of the first semiconductor layer facing toward the semiconductor substrate, the first semiconductor region having an impurity concentration that is higher than the impurity concentration of the first semiconductor layer;
selectively forming a second semiconductor region of a second conductivity type in the first semiconductor layer;
forming a second semiconductor layer of the second conductivity type on the first side of the first semiconductor layer;
selectively forming in the second semiconductor layer, a third semiconductor region of the first conductivity type and having an purity concentration that is higher than the impurity concentration of the semiconductor substrate;
forming a plurality of trenches penetrating the third semiconductor region and the second semiconductor layer, and reaching the first semiconductor layer, bottoms of the plurality of trenches being in contact with the first semiconductor region; and
forming a gate electrode in each of the plurality of trenches via a gate insulating film, wherein
the first semiconductor region is constituted by a lower first semiconductor region and an upper first semiconductor region in contact with a surface of the lower first semiconductor region and having an impurity concentration that is lower than the impurity concentration of the lower first semiconductor region, and
selectively forming the first semiconductor region includes partially forming the lower first semiconductor region between the plurality of trenches and between the second semiconductor regions.

6. The method according to claim 5, wherein
the second semiconductor region is formed by multi-stage ion implantation having a plurality of acceleration energies, and a dose amount of an ion implantation at a lowest acceleration energy of the plurality of acceleration energies is greater than a dose amount of an ion implantation at another acceleration energy of the plurality of acceleration energies.

7. The method according to claim 5, wherein
the lower first semiconductor region is formed by multi-stage ion implantation having a plurality of acceleration energies, and a dose amount at a lowest acceleration energy of the plurality of acceleration energies is dose amount is greater than a dose amount of an ion implantation at another acceleration energy.
